(19) United States
(12) Patent Application Publication
(10) Pub. No.: US 2026/0186423 A1
(43) Pub. Date: Jul. 2, 2026

(54) CDU CORRECTION METHOD

(71) Applicant: Shanghai Huali Integrated Circuit Corporation, Shanghai (CN)

(72) Inventors: Kan ZHOU, Shanghai (CN); Wenzhan ZHOU, Shanghai (CN)

(73) Assignee: Shanghai Huali Integrated Circuit Corporation, Shanghai (CN)

(21) Appl. No.: 19/306,415

(22) Filed: Aug. 21, 2025

(30) Foreign Application Priority Data
Jan. 2, 2025 (CN) 202510008284.7

(51) Int. Cl. G03F 7/00

(52) U.S. Cl. CPC G03F 7/70625; G03F 7/70441; G03F 7/70558; G03F 7/70655; G03F 7/706831

(57) ABSTRACT

The present application discloses a CDU correction method comprising following steps: Step 1, identifying a plurality of weak points within a die, and forming measurement regions within the die centered around each of respective weak points; performing CD measurements on patterns within respective measurement regions to obtain a plurality of CD measurement values; Step 2, subtracting the corresponding CD target value from each of the respective CD measurement values corresponding to patterns within respective measurement regions to obtain corresponding CD offset values, and determining a distribution of CD offset values within the die based on distribution of corresponding patterns; Step 3, correcting CDU recipe based on distribution of the CD offset values in the respective measurement regions to obtain a corrected CDU recipe; Step 4, inputting the corrected CDU recipe into a lithography apparatus, wherein lithography apparatus performs exposure based on corrected CDU recipe to implement CDU correction.

### CROSS-REFERENCES TO RELATED APPLICATIONS

This application claims priority to Chinese patent application No. CN202510008284.7, filed on Jan. 2, 2025, the disclosure of which is incorporated herein by reference in its entirety.

### TECHNICAL FIELD

The present application relates to method for manufacturing semiconductor integrated circuit, and in particular to a critical dimension uniformity (CDU) correction method.

### BACKGROUND

As shown in FIG. 1, a flow chart of existing CDU correction method is illustrated. The existing CDU correction method comprises the following steps:

A lithography machine 101 is used to expose a wafer 201.

Subsequently, an etching apparatus is employed to etch the wafer 201. Before CDU correction, the CDU data obtained after etching tends to be poor.

Thereafter, proceed with the step marked as 104, which involve measuring the critical dimensions (CD) and forming a CD map. The diagram labeled as reference numeral 202 represents a CD map. Each coordinate on the CD map corresponds one-to-one with a specific location on the wafer. The CD map displays critical dimension values at the respective coordinate positions.

As shown in FIG. 2, a distribution diagram of CDU marks 205 within the exposure region 204 in the existing CDU correction method is illustrated. In the existing method, CD measurement is performed by measuring CDU marks 205 placed on scribe lanes. By placing a large number of CDU marks 205 to cover the entire exposure region 204 (also referred to as a shot) of the product, CDU correction can be achieved.

As shown in FIG. 3A, a schematic structural diagram of CDU mark 205 in existing CDU correction method is illustrated. The CDU mark 205 is essentially a one-dimensional dense line pattern 206 or dense trench pattern.

As shown in FIG. 3B, an SEM image of CDU mark 205 from FIG. 3A is illustrated. The line 206a is an SEM image of line 206 shown in FIG. 3A. The corresponding CD value can be obtained by analyzing the line 206a in FIG. 3B.

Returning to FIG. 1, the CDU optimization 105 is performed. Typically, the CDU optimization 105 is carried out using the IMO software of the lithography machine.

After the CDU optimization 105, a corrected recipe is obtained. The recipe usually comprises dose sub-recipe 106. The map 203 illustrates exposure dose control corresponding to dose sub-recipe 106, indicating the specified exposure dose values for different positions across the wafer.

When subsequent wafers are exposed, exposure process incorporates the correction information from the corrected recipe, thereby improving the CDU.

In the existing method, CDU correction is implemented through mark dose control. However, due to use of CDU marks, the existing method is subject to limitations associated with the marks themselves, resulting in the following drawbacks:
1. When chip patterns vary, different CDU mark designs are required for different products.
2. The method is constrained by layout limitations. For example, in large-die chip products, application of CDU correction based on CDU marks is limited, due to the inability to place a sufficient number of CDU marks within the die area.
3. The distribution of CDU marks is limited, leading to insufficient intra-field dose control within the exposure region.
4. Due to the limited number of CDU marks, the amount of CD measurement data is restricted, which makes it difficult to eliminate the metrology noise. As a result, only simple mark designs are used, most of which are one-dimensional.

### BRIEF SUMMARY

According to some embodiments in this application, a CDU correction method is disclosed in the following steps:
Step 1: identifying weak points within a die, and forming the measurement regions within the die centered around the respective weak points; performing critical dimension (CD) measurements on patterns within respective measurement regions to obtain a plurality of CD measurement values;
Step 2: subtracting a corresponding CD target value from each of the respective CD measurement values corresponding to the patterns within the respective measurement regions to obtain corresponding CD offset values; and
determining a distribution of CD offset values within the die based on distribution of the corresponding patterns;
Step 3: correcting CDU recipe based on the distribution of the CD offset values in the respective measurement regions to obtain a corrected CDU recipe;
Step 4: inputting the corrected CDU recipe into a lithography apparatus, wherein the lithography apparatus performs exposure based on corrected CDU recipe to implement CDU correction.

A further improvement is to utilize OPC software to find each of the weaknesses.

A further improvement is to obtain each of the CD measurement values by the SEM measurement.

In some cases, field of view (FOV) of scanning electron microscope (SEM) is greater than 2 micrometers by 2 micrometers.

In some cases, the respective patterns within respective measurement regions are identical or different.

In some cases, step 2 further comprises:
calculating an average value of CD measurement values within each of respective measurement regions to obtain a virtual CD value corresponding to respective measurement regions, and
Step 3 further comprises correcting the CDU recipe using the virtual CD values.

In some cases, step 2 further comprises:
calculating an average value of the CD offset values within each of the respective measurement regions to obtain a CD offset average value, and
in Step 3, the CD offset average value is used as a common correction value for the various patterns within each of respective measurement regions, and CDU recipe is corrected using the correction value.

In some cases, the CD target value is provided by optical proximity correction (OPC) software.

In some cases, the CDU recipe includes a dose control sub-recipe for controlling exposure dose, and the correction of CDU recipe includes correction of the dose control sub-recipe.

In some cases, in Step 1, the CD measurements are performed on the patterns in all directions within each of the respective measurement regions.

In some cases, no CDU mark is disposed on a scribe lane of the die.

In some cases, in Step 1, the wafer which is corresponding to the die has undergone lithography process in the lithography apparatus controlled by the uncorrected CDU recipe from Step 3, and has also undergone the etching process.

In some cases, after Step 4, the corrected CDU recipe is used as the CDU recipe for the lithography apparatus in a subsequent lithography process.

In some cases, the Steps 1 through 4 are repeated one or more times such that the CDU meets process requirements.

Compared with the conventional technology that relies on CDU marks for the CDU correction, the present application achieves CDU correction by directly measuring the device patterns within the die, without requiring the use of CDU marks. Therefore, CDU correction performance of the present application is not constrained by limitations associated with CDU marks, such as the number or arrangement of CDU marks, thereby enabling improved CDU correction results.

Compared with the conventional methods that use CDU marks, the improved CDU correction performance of the present application is further reflected in the following:

Since the present application achieves the CDU correction by directly using device pattern within the die, changes in device patterns within the die do not affect CDU correction performance. In contrast, in conventional methods, when CDU marks are applied to different device patterns within different dies, the resulting CDU correction performance often varies and may fail to achieve the desired level of correction.

Since the present application does not require the placement of CDU marks, it is not limited by the layout of the die and is thus applicable to all products. In contrast, conventional methods require CDU marks to be placed within the layout. For products with large dies, it is often not possible to place a sufficient number of CDU marks, thereby preventing effective CDU correction for large dies.

In the present application, the device patterns within the die used for CDU correction are densely and uniformly distributed, which effectively enhances control of exposure dose across the exposure field, thereby improving CDU correction performance within exposure field. In contrast, conventional methods have limited distribution of CDU marks, resulting in insufficient exposure dose control within exposure field and thus limiting the CDU correction effectiveness.

The device patterns within the die of the present application can provide massive amounts of data and metrology settings based on Graphic Data System (GDS) files, enabling application of complex two-dimensional patterns. In conventional methods, due to the limited amount of data provided by CDU marks and the inability to avoid the metrology noise, only simple mark designs can be used, most of which are one-dimensional.

### BRIEF DESCRIPTION OF THE DRAWINGS

Further detailed description of present application will be given below in conjunction with the accompanying drawings and specific embodiments:

FIG. 1 is a flow chart of a conventional CDU correction method;

FIG. 2 is a distribution diagram of the CDU marks within the exposure field in the conventional CDU correction method;

FIG. 3A is a schematic structural diagram of a CDU mark in the conventional CDU correction method;

FIG. 3B is an SEM image of the CDU mark shown in FIG. 3A;

FIG. 4 is a flow chart of a CDU correction method according to the embodiment of the present application;

FIG. 5 is a distribution diagram of weak points, i.e., hot spots (HS), within exposure field according to the embodiment of the present application;

FIG. 6 is a photograph of a measurement region during CD measurement process in the CDU correction method according to the embodiment of the present application;

FIG. 7 is a comparative diagram of CDU improvement between the CDU correction method according to embodiment of the present application and conventional CDU correction method.

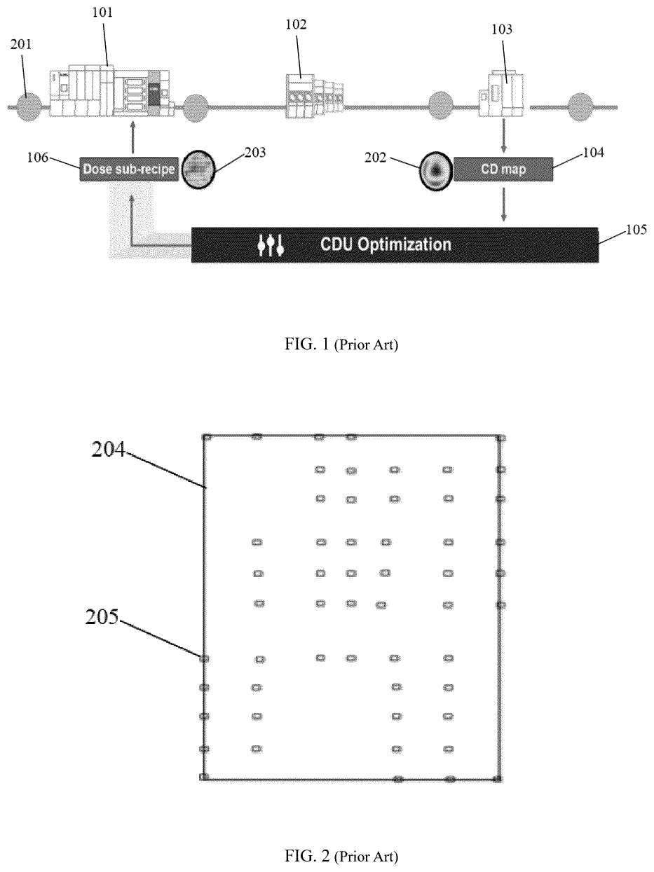

### DETAILED DESCRIPTION OF THE DISCLOSURE

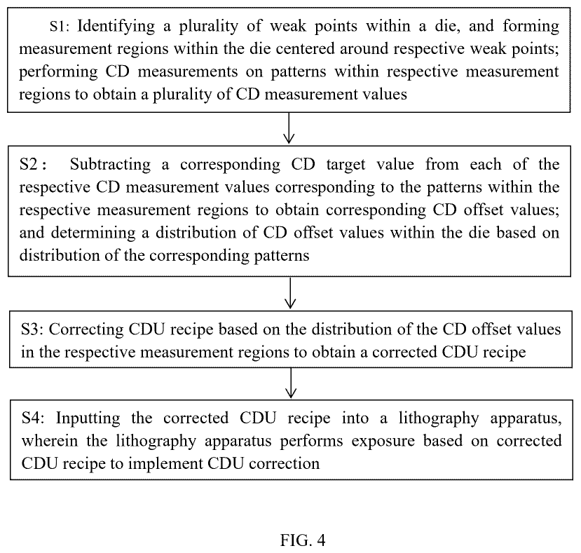

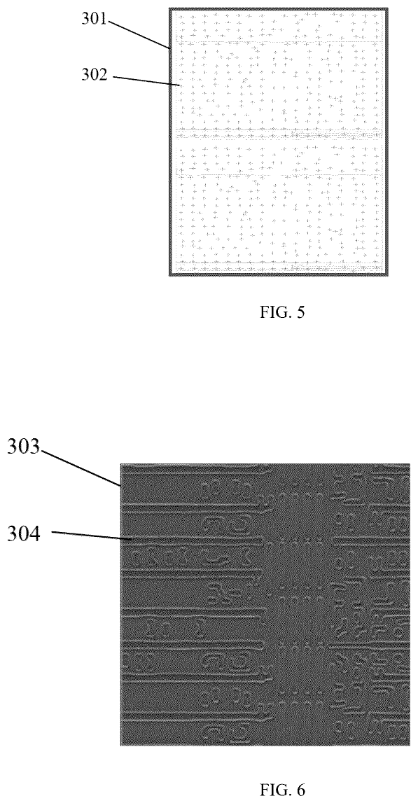

As shown in FIG. 4, a flow chart of the CDU correction method according to the embodiment of the present application is provided. As shown in FIG. 5, a distribution diagram of weak points 302 within the exposure field in the CDU correction method according to the embodiment of the present application is provided. As shown in FIG. 6, a photograph of the measurement region during critical dimension measurement process in the CDU correction method according to the embodiment of present application is provided. The CDU correction method according to the embodiment of the present application comprises the following steps:
Step 1: As shown in FIG. 5, multiple weak points 302 within the die are identified.

FIG. 5 illustrates the range of an exposure field, which typically includes more than one die.

In the embodiment of the present application, the OPC software is used to find each of the weaknesses 302.

In some embodiments, the number of the weak points 302 is greater than one. When there are many weak points 302, multiple weak points 302 with the higher importance may be selected based on their significance.

The measurement regions within the die are formed centered around each of weak points 302. The critical dimensions (CD) of the patterns within each measurement region are measured to obtain multiple CD measurement values.

In the embodiment of the present application, SEM metrology is used to obtain the CD measurement values.

The measurement regions are determined based on the field of view (FOV) of the SEM, and generally, largest possible FOV is used for measurement. In some embodiments, the FOV of the SEM is greater than 2 μm×2 μm.

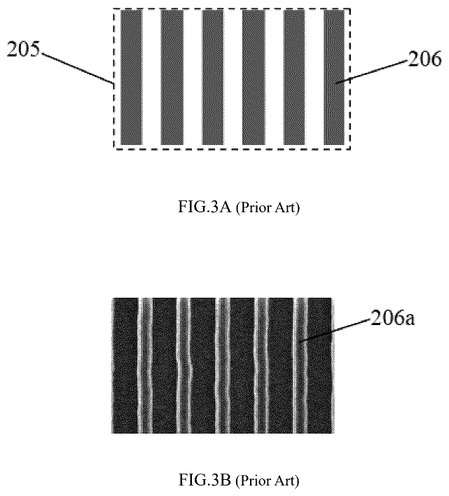

The patterns within each of the measurement region may be identical or different. As shown in FIG. 6, image 303 is an SEM image of one measurement region. The image 303 shows the multiple patterns 304, which can be seen to be either identical or different. In the embodiment of the present application, critical dimensions of patterns in all directions within each measurement region are measured. This differs from the conventional method shown in FIG. 3A, where critical dimension measurement is performed only on pattern 206 of the CDU mark in a single direction.

In the embodiment of the present application, no CDU mark is arranged on the scribe lanes of the dies. Accordingly, in the embodiment of present application, CDU correction can be achieved without using CDU marks, thereby overcoming various shortcomings associated with using CDU marks for CDU correction.

The wafer corresponding to the die has undergone a lithography process controlled by the CDU recipe before correction (as described in Step 3 below) in lithography apparatus, and has also undergone an etching process.
Step 2: The corresponding CD offset values are derived by subtracting the target CD values from the measured CD values within each measurement region.

The calculation formula of the CD offset value is as follows:

$$CD\_bias = CD\_measure - CD\_target ; \qquad ( 1 )$$

In formula (1), CD_bias represents the CD offset value, CD_measure represents the measured CD value, and CD_target represents the target CD value.

Based on the distribution of the patterns corresponding to the respective CD offset values, the distribution of CD offset values within the die is obtained. In other words, a CD offset map is generated. The map indicates a one-to-one correspondence between coordinates on the map and the corresponding coordinates on the actual wafer, with the CD offset values displayed at the corresponding coordinates on the map.

In the embodiment of the present application, target CD values are provided by OPC software.

In the embodiment of the present application, it further includes:

Calculating an average of CD measurement values within each of the measurement regions to obtain a corresponding virtual CD value for each measurement region.

The virtual CD value is calculated using the following formula:

$$CD\_virtual = ( {\sum }_{k = 1}^{n} {CD\_measure}_{k} ) / n ; \qquad ( 2 )$$

In formula (2), CD_virtual represents the virtual CD value, k denotes the index of a pattern within the measurement region, n represents the total number of patterns within the measurement region, and CD_measureₖ represents CD measurement value of the k-th pattern within the measurement region.

In the embodiment of the present application, it further includes:

CD offset values within each measurement region are averaged to obtain average CD offset value.

The average CD offset value is calculated by the following formula:

$$bias\_mean = ( {\sum }_{k = 1}^{n} {CD\_bias}_{k} ) / n ; \qquad ( 3 )$$

In formula (3), bias_mean represents average CD offset value, and CD_biasₖ represents the CD offset value of the k-th pattern within the measurement region.
Step 3: The CDU recipe is corrected based on distribution of the CD offset values in each measurement region to obtain a corrected CDU recipe.

In the embodiment of the present application, the method further includes correcting the CDU recipe using the virtual CD value.

In the embodiment of the present application, the method further includes: using the average CD offset value as the common correction value for various patterns in each of the measurement regions, and correcting the CDU recipe based on the correction value.

In the embodiment of the present application, R value of correction value is average of R values of all patterns within all measurement regions. The R value represents correction ratio, that is, the correction ratio of the exposure dose. In some embodiments, the specific R value can be obtained through OPC simulation.

The upper and lower limits of the correction value are defined by the edge limit (EL) values verified from process window of similar products. In some embodiments, the specific EL values can be obtained through OPC simulation.

In the embodiment of the present application, the CDU recipe includes a sub-recipe for exposure dose control, which is used to control the exposure dose. The correction of CDU recipe includes the correction of the exposure dose control sub-recipe.
Step 4: CDU correction recipe is input into lithography apparatus, which performs exposure using the CDU correction recipe to achieve CDU correction.

After step 4 is completed, the CDU correction recipe is used as the CDU recipe in subsequent lithography processes performed by the lithography apparatus.

In some embodiments, Steps 1 to 4 are repeated more than once until CDU meets process requirements.

Compared with prior art that requires use of CDU marks to achieve CDU correction, embodiment of present application directly performs CDU correction based on measurements of device patterns within the die, without the need to use CDU marks. Therefore, the CDU correction effect of the embodiment of the present application is not limited by the quantity or arrangement of CDU marks, and thus can achieve improved CDU correction performance.

Compared with existing methods using CDU marks, the embodiment of the present application further improves CDU correction performance in the following aspect:

Since embodiment of the present application performs CDU correction directly based on device patterns within the die, changes in device patterns within the die do not affect CDU correction performance. In contrast, in existing methods, CDU correction performance often varies when the same CDU marks are applied to different device patterns within the die, and often fails to achieve the desired correction results.

Since the embodiment of the present application does not require the CDU marks, it is not constrained by layout of the die and is applicable to all products. In contrast, in existing methods, CDU marks must be placed within layout. For products with large dies, it is often not feasible to place a sufficient number of CDU marks, which makes it difficult to perform CDU correction for large dies.

In embodiment of the present application, device patterns used for CDU correction are densely and uniformly distributed within the die. This enhances control of exposure dose within the exposure region and thereby improves CDU correction within the exposure region. In contrast, in the existing methods, the distribution of CDU marks is limited, which leads to insufficient exposure dose control in exposure region and restricts the effectiveness of CDU correction within the exposure region.

The device patterns within the die in embodiment of present application are capable of providing a vast amount of data, along with metrology settings based on GDS file, thereby enabling application of the complex two-dimensional pattern designs. In contrast, in existing methods, amount of data provided by CDU marks is limited, which makes it difficult to avoid metrology noise. Moreover, CDU marks can only utilize simple mark designs, most of which are one-dimensional.

The experimental validation has shown that, prior to performing the CDU correction according to the embodiment of the present application, the 3σ of the CD distribution was 1.87 nm. After applying the CDU correction method of the embodiment of the present application, the 3σ of the CD distribution was reduced to 0.81 nm.

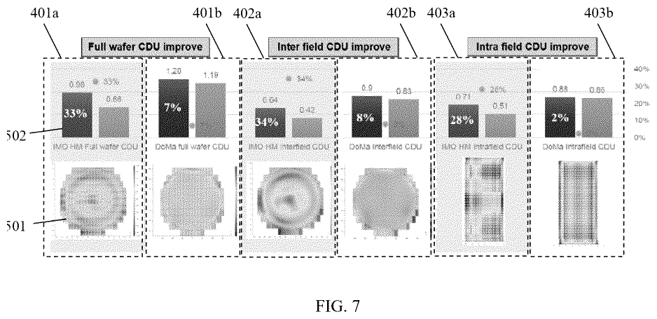

Compared with existing CDU correction method using CDU marks, the method of embodiment of the present application achieves better CDU correction performance. As shown in FIG. 7, which is a comparison chart of the CDU improvement between CDU correction method of the embodiment of the present application and the existing method, the data in FIG. 7 is based on a 28HK product. FIG. 7 includes the following:

The dashed box 401a contains comparative CDU data of full-wafer hard mask (HM) using IMO. IMO refers to the lithography tool software, through which the CDU correction is implemented.

The dashed box 401b contains comparative full wafer CDU data for dose correction using Dose Mapper (DOMA), where CDU correction is implemented via DOMA.

The dashed box 402a contains comparative inter-exposure area CDU data for IMO HM.

The dashed box 402b contains the comparative inter-exposure area CDU data for DOMA.

The dashed box 403a contains comparative intra-exposure area CDU data for IMO HM.

The dashed box 403b contains the comparative intra-exposure area CDU data for DOMA.

Each of the above two sets of comparative data includes:

The CDU map in dashed box 401a is indicated by reference numeral 501.

The CDU bar chart in dashed box 401a is indicated by reference numeral 502.

In the CDU bar chart, the left bar represents CDU value after CDU correction using the method of the embodiment of the present application, and the right bar represents the CDU value after CDU correction using the existing method. In dashed box 401a, the value of the left bar is 0.98, and the value of the right bar is 0.66. The CDU value obtained by the method of embodiment of present application is improved by 33% compared to the existing method.

Similarly, in dashed box 401b, value of the left bar is 1.28 and value of the right bar is 1.19, indicating that the CDU value achieved using the method of the present embodiment is improved by 7% compared with the existing method.

In dashed box 402a, the value of the left bar is 0.64 and the value of the right bar is 0.42, indicating a 34% improvement.

In dashed box 402b, the value of the left bar is 0.90 and the value of the right bar is 0.83, indicating an 8% improvement.

In dashed box 403a, the value of the left bar is 0.71 and the value of the right bar is 0.51, indicating a 28% improvement.

In dashed box 403b, the value of the left bar is 0.88 and the value of the right bar is 0.86, indicating a 2% improvement.

Therefore, as shown in FIG. 7, the method of embodiment of the present application provides an improvement in CDU over existing method.

The above description of specific embodiments is provided to illustrate principles of the present application in detail and should not be construed as limiting scope of the invention. Various modifications and alterations may be made by those skilled in art without departing from spirit and scope of invention, and all such modifications and equivalents are intended to be included within the scope of the present application.

What is claimed is:

1. A CDU correction method, comprising the following steps:
Step 1: identifying a plurality of weak points within a die, and forming measurement regions within the die centered around respective weak points; performing CD measurements on patterns within respective measurement regions to obtain a plurality of CD measurement values;
Step 2: subtracting a corresponding CD target value from each of the CD measurement values corresponding to the patterns within the respective measurement regions to obtain corresponding CD offset values, and
determining a distribution of CD offset values within the die based on the distribution of the corresponding patterns;
Step 3: correcting CDU recipe based on the distribution of the CD offset values in the respective measurement regions to obtain a corrected CDU recipe;
Step 4: inputting the corrected CDU recipe into a lithography apparatus.

2. The CDU correction method according to claim 1, wherein OPC software is used to find each of the weaknesses.

3. The CDU correction method according to claim 1, wherein each of the CD measurement values is obtained by SEM measurement.

4. The CDU correction method according to claim 3, wherein a FOV of the SEM is greater than 2 micrometers by 2 micrometers.

5. The CDU correction method according to claim 1, wherein the respective patterns within the respective measurement regions are identical or different.

6. The CDU correction method according to claim 5, wherein Step 2 further comprises:
calculating an average value of CD measurement values within each of the respective measurement regions to obtain a virtual CD value corresponding to respective measurement regions, and
Step 3 further comprises correcting the CDU recipe using the virtual CD values.

7. The CDU correction method according to claim 6, wherein the step 2 further comprises:
calculating an average value of the CD offset values within respective measurement regions to obtain a CD offset average value, and
in Step 3, the CD offset average value is used as a common correction value for the various patterns within each of respective measurement regions, and CDU recipe is corrected using the correction value.

8. The CDU correction method according to claim 1, wherein the CD target value is provided by OPC software.

9. The CDU correction method according to claim 1, wherein the CDU recipe includes a dose control sub-recipe for controlling exposure dose, and the correction of CDU recipe includes correction of the dose control sub-recipe.

10. The CDU correction method according to claim 3, wherein in Step 1, CD measurements are performed on patterns in all directions within each of the respective measurement regions.

11. The CDU correction method according to claim 1, wherein no CDU mark is disposed on a scribe lane of the die.

12. The CDU correction method according to claim 1, wherein in Step 1, the wafer which is corresponding to the die has undergone the lithography process in the lithography apparatus controlled by the uncorrected CDU recipe from Step 3, and has also undergone the etching process.

13. The CDU correction method according to claim 12, wherein after Step 4, the corrected CDU recipe is used as CDU recipe for the lithography apparatus in a subsequent lithography process.

14. The CDU correction method according to claim 13, wherein the Step 1 through Step 4 are repeated one or more times so that the CDU meets process requirements.
